(19) United States
(12) Patent Application Publication
(10) Pub. No.: US 2004/0237888 A1
(43) Pub. Date: Dec. 2, 2004

(54) Optical monitoring system for plasma enhanced chemical vapor deposition

(75) Inventors: Peter Joseph Codella, Niskayuna, NY (US); Manisha Tinani, Albany, NY (US); George Theodore Dalakos, Niskayuna, NY (US); Eric Michael Breitung, Albany, NY (US)

Correspondence Address: General Electric Company, CRD Patent Docket Rm 4A59, P.O. Box 8, Bldg. K-1, Schenectady, NY, 12301, US

(73) Assignee: General Electric Company

(21) Appl. No.: 10/449,975

(22) Filed: May 30, 2003

(51) Int. Cl. C23C 16/00; C23F 1/00

(52) U.S. Cl. 118/712; 427/569; 156/345.24

(57) ABSTRACT

An optical monitoring system for a plasma enhanced chemical vapor deposition (PECVD) apparatus includes a light source for generating an input light beam, and a first port configured within the PECVD apparatus for receiving the input light beam from the light source. The first port is configured to direct the input beam upon a workpiece within the PECVD apparatus. A second port is configured within the PECVD apparatus for receiving an output light beam passed through the workpiece, and a comparing mechanism for comparing the output light beam with the input light beam is configured to determine a deposited layer thickness upon the workpiece.

### BACKGROUND OF INVENTION

The present disclosure relates generally to process monitoring systems for thin film deposition and, more particularly, to an optical monitoring system for plasma enhanced chemical vapor deposition processes.

One of the primary steps in the fabrication of modern semiconductor devices is the formation of a thin layer or film on a semiconductor substrate or other workpiece by chemical reaction of gases. Such a deposition process is generally referred to as chemical vapor deposition (CVD). Conventional CVD processes supply reactive gasses to the substrate surface where heat-induced chemical reactions take place to produce a desired layer (e.g., silicon oxide, silicon nitride). In contrast, a plasma-enhanced chemical vapor deposition (PECVD) process promotes excitation and/or dissociation of the reactant gases by the application of radio-frequency (RF) energy to a reaction zone near the surface, thereby creating a plasma. The high reactivity of the species in the plasma reduces the energy required for a chemical reaction to take place, and thus lowers the operating temperature as compared with conventional thermal CVD processes.

In most applications, a thin film layer is deposited over existing features on a device. Accordingly, thin film deposition is an inherently complex process that can be difficult to simultaneously control certain film characteristics, such as optical properties, electrical properties and stresses, while maintaining uniform thickness. In particular, PECVD introduces both radial and azimuthal thickness non-uniformities within and among wafers.

Multi-layer film designs are based on the refractive index and thickness of each layer. Using the PECVD technique, film thickness is generally controlled by adjusting the deposition time with the process running at a constant, known rate. The refractive index is controlled by the process conditions. Although these controls are sufficient for simple film designs having a large tolerance for error in the thickness and/or refractive index thereof, more advanced applications demand tighter process controls. As a result, some form of real-time or in-situ monitoring with feedback control is typically implemented to achieve tighter-tolerance designs.

Heretofore, conventional real-time monitoring systems of other thin film deposition processes such as sputtering, thermal evaporation, etc., have included ellipsometry, transmission, reflectance, or mass gain by QCM (Quartz Crystal Microbalance). In some instances, monitoring is done on witness samples introduced into the process. In the case of PECVD, ellipsometry and reflectance have been used, however no real-time monitoring in transmission mode has been reported. In addition, ellipsometry fails to provide precise information for films having the requisite thickness in the more complicated designs. Reflectance measurements also present unique problems with internal reflections that limit measurement accuracy.

Therefore, it is desirable to be able to achieve improvements in advanced process control and monitoring of plasma-enhanced chemical vapor deposition processes.

### SUMMARY OF INVENTION

The above discussed and other drawbacks and deficiencies of the prior art are overcome or alleviated by an optical monitoring system for a plasma enhanced chemical vapor deposition (PECVD) apparatus. In an exemplary embodiment, the system includes a light source for generating an input light beam, and a first port configured within the PECVD apparatus for receiving the input light beam from the light source. The first port is configured to direct the input beam upon a workpiece within the PECVD apparatus. A second port is configured within the PECVD apparatus for receiving an output light beam passed through the workpiece, and a comparing mechanism for comparing the output light beam with the input light beam is configured to determine a deposited layer thickness upon the workpiece.

In another aspect, a plasma enhanced chemical vapor deposition (PECVD) apparatus includes a radio frequency (RF) electrode assembly disposed within a deposition chamber and a lower electrode configured to support a workpiece thereon. The RF electrode assembly includes a first port configured to guide an externally generated input optical beam therethrough and incident upon the workpiece, and the lower electrode assembly includes a second port configured to guide an output optical beam passed through the workpiece out of the deposition chamber.

In still another aspect, a method for optically monitoring a plasma enhanced chemical vapor deposition (PECVD) process includes generating an input light beam and directing the input light beam through a first port configured within a PECVD apparatus upon a workpiece disposed within the PECVD apparatus. An output light beam is received through a second port configured within the PECVD apparatus, the output light beam passed through the workpiece. The output light beam is compared with the input light beam so as to determine a deposited layer thickness upon the workpiece.

### BRIEF DESCRIPTION OF DRAWINGS

Referring to the exemplary drawings wherein like elements are numbered alike in the several Figures:

FIG. 1 is a schematic diagram of an optical monitoring system for a plasma enhanced chemical vapor deposition (PECVD) apparatus, in accordance with an embodiment of the invention;

FIG. 2 is a schematical top and side sectional view of an RF electrode assembly of the PECVD reactor prior to the modification thereof;

FIG. 3 is an exploded sectional view of the modified RF electrode assembly of FIG. 1, in accordance with a further aspect of the present invention; and

FIG. 4 is a sectional schematic view illustrating the second, lower port and modified bottom electrode in greater detail.

### DETAILED DESCRIPTION

Disclosed herein is an optical monitoring system that has been incorporated in a commercial PECVD reactor in order to provide real-time control over a thin film deposition process upon a workpiece. This control feature allows for the construction of multi-layer films used in advanced applications wherein precise film thicknesses are desired. Briefly stated, an optical monitoring system is configured to direct a controlled beam of light through a workpiece residing in the deposition chamber. The light passing through the workpiece is collected and compared with the incident light so as to determine the thickness of the layer as it is being deposited.

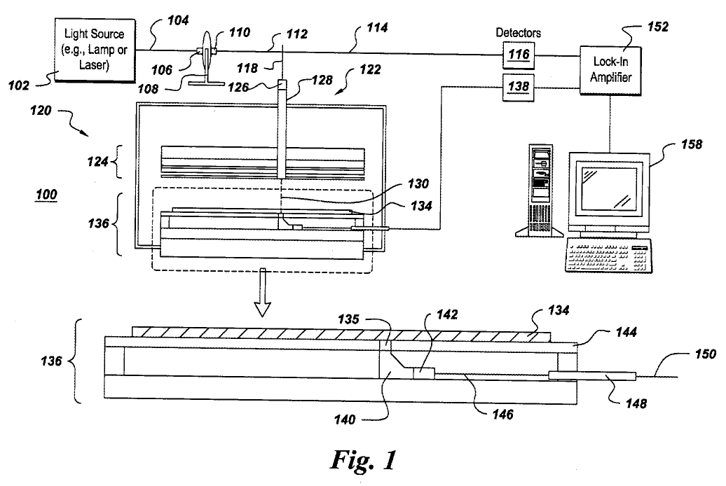

Referring to FIG. 1, there is shown a schematic diagram of an optical monitoring system 100 for a plasma enhanced chemical vapor deposition (PECVD) apparatus, in accordance with an embodiment of the invention. In the example depicted, optical monitoring system 100 is used in conjunction with a PlasmaTherm® reactor. However, it will be appreciated that the principles of the present disclosure may be incorporated into other types of deposition/etching equipment.

The system 100 includes a light source 102, such as a white light, laser, diode, or any suitable light emitting device. Light generated by source 102 is directed through a waveguide 104 (e.g., a single optical fiber) to a first collimator 106, optical chopper 108 and second collimator 110. It will be appreciated that although the use of fiber optics simplifies the channel of light and is particularly desirable for laser-based applications, other types of waveguides may also be utilized. At the output of collimator 110, the light is split into two beams and directed through a bifurcated fiber bundle 112. One beam is sent through a first optical path 114 toward a first optical detector 116 for use as a reference beam, while the other beam is sent through a second optical path 118 to a PECVD reactor 120.

The light beam directed toward the reactor 120 enters therein through a first custom port 122 configured through the RF electrode assembly 124 thereof, as described in greater detail hereinafter. However, illustrated schematically in FIG. 1 is a third collimator 126 and ceramic spacer 128 for providing thermal and electrical isolation of the RF electrode assembly 124. The port 122 allows the beam 130 to enter the deposition chamber 132 directly above a workpiece 134 situated therein. The beam 130 then passes through the workpiece 134 and exits through a second custom port 135 configured in a lower electrode assembly 136. Once passed through workpiece 134, the exiting light is collected and directed out of the reactor 120 to a second optical detector 138.

As shown in the lower insert of FIG. 1, a 90 degree optical reflector 140 redirects the output beam to a fourth collimator 142 that is particularly suited for a high temperature environment, given that the lower electrode assembly 136 may be heated by heating element 144 (depending on the reactants used in the PECVD process). A high temperature fiber 146 carries the output beam from collimator 142 out of the reactor 120 through a vacuum sealed tube 148. Another fiber 150 may be used to deliver the output light to the second optical detector 138.

The signals from the two detectors 116, 138 are fed to a lock-in amplifier 152 that measures the contrast between the “light” and “dark” signals (as the result of using chopper 108) of both the reference beam signal 154 and the output beam signal 156. In addition, the amplifier 152 records the signal intensity ratio of the light and dark signals between the reference beam signal 154 and the output beam signal 156. Finally, this data is processed by a suitable processor 158, such as a personal computer or other workstation so as to determine the optical response and thin film thickness of the workpiece 134.

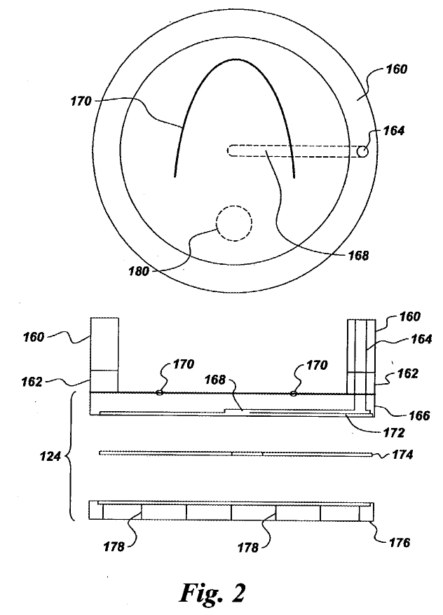

FIG. 2 is a schematical top and side sectional view of an RF (i.e., top) electrode assembly 124 of the PECVD reactor 120 prior to the modification thereof for accommodating the first custom port and optical monitoring beam. The RF electrode 124 is temperature controlled and conveys both the gaseous reactants and the RF energy into the reactor. As indicated previously, the RF electrode assembly 124 is both electrically and thermally isolated from an outer wall 160 of the reactor by a ceramic spacer 162. For ease of illustration, the outer wall 160 and ceramic spacer 162 is shown in FIG. 2, but not in FIG. 1. The gaseous reactants are introduced into the RF electrode assembly 124 via a tube 164 formed through the outer wall 160 and ceramic spacer 162. Once inside the top electrode portion 166 of RF electrode assembly 124, the reactants are directed toward the center thereof through horizontal tube portion 168. The top electrode portion 168 receives the RF energy and is temperature controlled, such as through a water circulation path 170.

From the center of the top electrode portion 166, the reactants move down into a gas distribution chamber 172 and diffusion plate 174 disposed over a “showerhead” 176. As is known in the art, a showerhead includes numerous, regularly arrayed small pinholes 178 for distributing reactant gasses into the reaction volume. The size and distribution of the pinholes 178 are designed to yield a uniform gas field in the active reactor volume. In view of this configuration for the RF electrode assembly 124, and in further view of the desirability to gain optical access to the workpiece 134 within the reactor 120, the region approximated by the dashed circle 180 in FIG. 2 was identified as one possible location where modifying the electrode assembly 124 would not interfere with existing hardware or attachments.

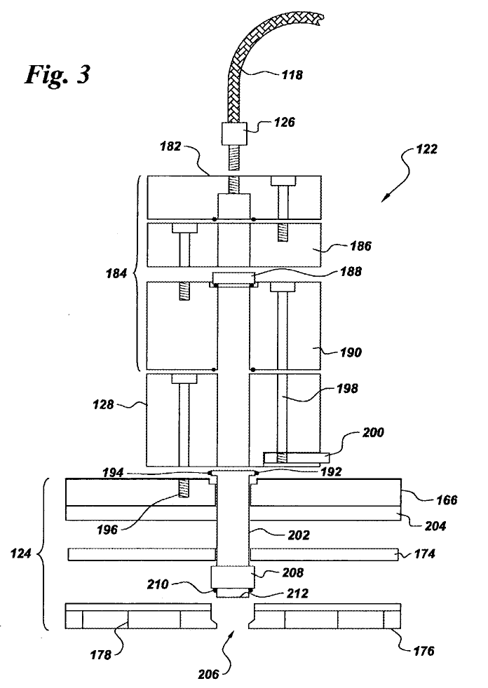

Referring now to FIG. 3, there is shown an exploded sectional view of the modified RF electrode assembly 124 of FIG. 1, particularly illustrating the first port 122 for facilitating the application of a light beam within the reactor chamber 132. As is shown, optical fiber (path) 118 and collimator 126 are threadingly engaged with, and mounted onto, a tilt plate 182 that allows directional adjustment of the beam emerging from the lens of collimator 126. A spacer 184 includes an aluminum window seal plate 186 (not shown in the system schematic of FIG. 1) used to hold and seal an optical window 188 that passes the light outputted from collimator 126. In so doing, the optical window 188 provides a vacuum seal and isolates the chamber from ambient conditions. The spacer 184 further includes an optical path extension section 190, as well as the tilt plate 182.

As was described earlier, the ceramic spacer 128 isolates the RF energy applied to the electrode assembly 124, thereby confining it to the reactive area and away from the system operators. In order to secure the ceramic spacer 128 to the top electrode portion 166 of RF electrode assembly 124, a groove 192 is machined into top electrode portion 166 to accept a sealing o-ring 194, while threaded holes 196 are also formed to accept screws (not shown) for holding the ceramic spacer 128 in place. In addition, a hole 198 is also formed on the opposite side of ceramic spacer 128 to accept a bolt (not shown) for securing the aluminum spacer 184 thereto. This bolt mates with a nut 200 at the bottom of ceramic spacer 128. In one possible embodiment, bolt holes in each individual section of the aluminum spacer 184 and the ceramic spacer 128 are disposed in a circle with alternating positions being used to secure the top and bottom thereof.

The groove 192 in the top electrode portion 166 is also formed so as to accommodate the top of an isolation tube 202 that runs through the entire thickness of the RF electrode assembly 124. Accordingly, openings are formed through a sealing plate 204, diffusion plate 174 and the showerhead 176 to accommodate the isolation tube 202 therethrough. In particular, the hole 206 through showerhead 178 is larger in diameter at the upper portion thereof so as to receive a pressure ring 208 and o-ring 210 for sealing the tube 202 against the showerhead 176. It will be noted that the location of the hole 206 may be selected such that only one of the distribution pinholes 178 in the showerhead 176 need be eliminated. The o-ring 210 is seated using applied pressure to the spacers when the showerhead 176 is fastened as part of the electrode assembly 124. Finally, a small section of screen 212 is placed inside the bottom of the isolation tube 202 in order to provide RF continuity over the hole 206 and maintain a uniform field, thereby resulting in a uniform film thickness.

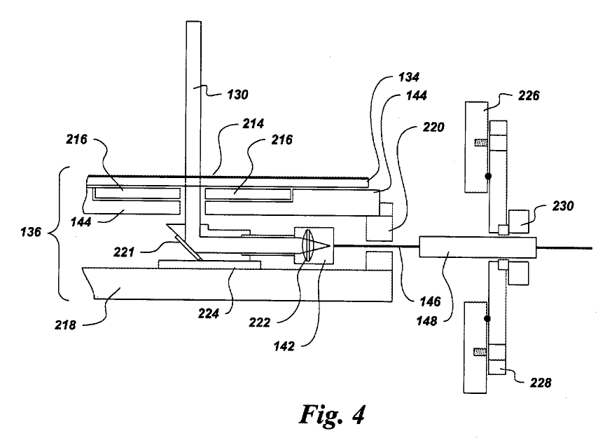

FIG. 4 is a sectional schematic view illustrating the second, lower port 135 and lower electrode assembly 136 in greater detail. This schematic illustrates the light beam 130 passing through the workpiece 134, which has a thin film 214 formed thereupon by PECVD. The heated electrode 144 supports the workpiece 134 thereon, and also includes a machined recess so as to allow the placement of one of a plurality of removable masks 216 therein. The particular mask 216 used will have a hole of a selected size or none at all, depending upon the amount of light desired to be passed through to the collimator 142. In certain instances, the mask 216 may be a solid plate transparent to the wavelength of interest while capable of thermal conductance such as, for example a silicon plate. This feature is particularly significant at high temperature operation where thermal uniformity is desirable.

A standard bottom electrode 218 is included at the bottom of the lower electrode assembly 136. This bottom electrode 218 includes embedded circulating coils (not shown) therein that can be used for either cooling or heating. However, since the heat range capability of the bottom electrode 218 is well below that desired for the present application, an additional heater (i.e., heated electrode 144) was constructed and mounted on a ceramic spacer 220. Below the heated electrode 144, a mirror 221redirects the beam 130 to a focusing lens 222 within collimator 142. The mirror 221, included within the 90° optical reflector 140 shown in FIG. 1, may be mounted upon an adjustable mounting bracket 224 so as to facilitate optimal light collection and compensate for minor misalignments of the entering beam 130. Because the optical components underneath heated electrode 144 are designed for a maximum temperature below the anticipated operating temperature, they are secured to the bottom, cooled electrode 218 for cooling thereof. Finally, the lens 222 transfers the light to the high-temperature optical fiber 146, which in turn is passed through the ceramic spacer 220 and through the vacuum sealed tube 148 surrounding the fiber 146. The tube 148 is sealed at the wall 226 of the reactor through a flange 228 and associated fitting 230.

As will be appreciated, the above described system allows for the implementation of a real-time, optical monitoring scheme within a PECVD reactor, notwithstanding the difficulties of a vacuum environment and line-of-sight limitations imposed by the deposition apparatus. In addition, a PECVD reactor introduces the additional challenge of having an RF electrode directly above the workpiece, with minimal space between the workpiece and the RF electrode. Furthermore, process constraints dictate that the applied RF field be uniform in order to achieve a stable deposition process and uniform film thickness. Thus, the limited distance between the top and bottom electrodes has made the insertion of optical beams very difficult heretofore in that any optical elements positioned in the deposition region would be coated, thereby making data interpretation difficult or impossible. Accordingly, the custom light beam entry port 122 described herein has addressed these problems and afforded direct illumination of the workpiece. Moreover, the custom port formed in the bottom electrode provides for the collection and redirection of the beam exiting the workpiece to allow measurement of light absorbed by the workpiece. Based on these absorption measurements, information about refractive index and film thickness is collected in real time and appropriate process control decisions may be made.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. An optical monitoring system for a plasma enhanced chemical vapor deposition (PECVD) apparatus, comprising:
a light source for generating an input light beam;
a first port configured within the PECVD apparatus for receiving said input light beam from said light source, said first port configured to direct said input beam upon a workpiece within the PECVD apparatus;
a second port configured within the PECVD apparatus for receiving an output light beam passed through said workpiece; and
a comparing mechanism for comparing said output light beam with said input light beam so as to determine a deposited layer thickness upon said workpiece.

2. The system of claim 1, further comprising:
an optical chopper for chopping said input light beam, said input light beam further being split into a first portion and a second portion, said first portion being directed through said first port and said second portion directed to a first optical detector; and
a second optical detector for receiving said output beam from said second port.

3. The system of claim 2, wherein said first port is formed within an upper, radio frequency (RF) electrode assembly of the PECVD apparatus.

4. The system of claim 2, wherein said second port is formed within a lower electrode assembly of the PECVD apparatus.

5. The system of claim 2, wherein said comparing mechanism for comparing further comprises:
a lock-in amplifier for receiving a reference beam signal generated by said first optical detector and an output beam signal generated by said second optical detector, said reference beam signal indicative of the intensity of said input light beam and said output beam signal indicative of the intensity of said output light beam; and
a processor for comparing said reference beam signal and said output light beam signal received by said lock-in amplifier.

6. The system of claim 2, further comprising:
a first collimator coupled to the output of said light source;
a second collimator coupled to the output of said optical chopper; and
a third collimator coupled to a spacer, said spacer providing thermal and RF isolation between said third collimator and a radio frequency (RF) electrode assembly of the PECVD apparatus.

7. The system of claim 2, wherein said PECVD apparatus further comprises:
a radio frequency (RF) electrode assembly disposed within a deposition chamber;
a lower electrode assembly configured to support said workpiece thereon.

8. The system of claim 7, further comprising:
a first spacer in communication with said RF electrode assembly;
a second spacer in communication with said first spacer, said second spacer having a collimator coupled thereto; and
an isolation tube disposed through said RF electrode assembly, said isolation tube located so as to direct said first portion of said input light beam from said optical source through said workpiece.

9. The system of claim 8, wherein said second spacer further comprises:
a tilt plate for directional adjustment of said first portion of said input light beam;
an optical path extension section adjacent said first spacer;
a pressure plate section between said tilt plate and said optical path extension section; and
an optical window sealed between said pressure plate section and said optical path extension section.

10. The system of claim 7, wherein said lower electrode assembly further comprises:
a heatable electrode supporting said workpiece;
a bottom electrode; and
an optical reflector supported by said bottom electrode, wherein said optical reflector is configured to redirect said output beam.

11. A plasma enhanced chemical vapor deposition (PECVD) apparatus, comprising:
a radio frequency (RF) electrode assembly disposed within a deposition chamber;
a lower electrode assembly configured to support a workpiece thereon;
said RF electrode assembly including a first port configured to guide an externally generated input optical beam therethrough and incident upon said workpiece; and
said lower electrode assembly including a second port configured to guide an output optical beam passed through said workpiece out of said deposition chamber.

12. The apparatus of claim 11, further comprising:
a first spacer in communication with said RF electrode assembly;
a second spacer in communication with said first spacer, said second spacer having an input optical source coupled thereto; and
an isolation tube disposed through said RF electrode assembly, said isolation tube located so as to direct an optical beam from said optical source through said workpiece.

13. The apparatus of claim 12, wherein:
a first end of said isolation tube is seated within a recess formed within a top electrode portion of said RF electrode assembly; and
a second end of said isolation tube is sealed against a showerhead of said RF electrode assembly.

14. The apparatus of claim 13, further comprising a screen disposed over said second end of said isolation tube.

15. The apparatus of claim 12, wherein said first spacer further comprises a ceramic spacer.

16. The apparatus of claim 11, wherein said lower electrode assembly further comprises:
a heatable electrode supporting said workpiece;
a bottom electrode; and
an optical reflector supported by said bottom electrode, wherein said optical reflector is configured to redirect said output optical beam.

17. The apparatus of claim 16, wherein said heatable electrode further includes a recess for receiving a removable mask therein, said removable mask having a hole of a selected size therethrough.

18. The apparatus of claim 16, further comprising:
a collimator for receiving said output beam reflected by said optical reflector;
an optical fiber for guiding said output beam from said collimator; and
a vacuum sealed tube for passing said optical fiber out from said deposition chamber.

19. The apparatus of claim 12, wherein said second spacer further comprises:
a tilt plate for directional adjustment of said input optical beam;
an optical path extension section adjacent said first spacer; and
a pressure plate section between said tilt plate and said optical path extension section.

20. The apparatus of claim 19, further comprising an optical window sealed between said pressure plate section and said optical path extension section.

21. A method for optically monitoring a plasma enhanced chemical vapor deposition (PECVD) process, the method comprising:
generating an input light beam;
directing said input light beam through a first port configured within a PECVD apparatus upon a workpiece disposed within the PECVD apparatus;
receiving an output light beam through a second port configured within said PECVD apparatus, said output light beam passed through said workpiece; and
comparing said output light beam with said input light beam so as to determine a deposited layer thickness upon said workpiece.

22. The method of claim 21, further comprising:
chopping said input light beam and splitting said input light beam into a first portion and a second portion, said first portion being directed through said first port and said second portion directed to a first optical detector; and
receiving said output beam from said second port at a second optical detector.

23. The method of claim 22, wherein said comparing further comprises:
receiving, with a lock-in amplifier, a reference beam signal generated by said first optical detector and an output beam signal generated by said second optical detector, said reference beam signal indicative of the intensity of said input light beam and said output beam signal indicative of the intensity of said output light beam; and
comparing, with a processor, said reference beam signal and said output light beam signal received by said lock-in amplifier.
